(19) United States
(12) Patent Application Publication
(10) Pub. No.: US 2015/0109060 A1
(43) Pub. Date: Apr. 23, 2015

(54) PROCESS, VOLTAGE AND TEMPERATURE COMPENSATED OSCILLATOR

(71) Applicant: RICHTEK TECHNOLOGY CORP, Hsinchu (TW)

(72) Inventors: Yen-Yin Huang, Hsinchu (TW); Ming-Shih Yu, Hsinchu (TW)

(73) Assignee: RICHTEK TECHNOLOGY CORP, Hsinchu (TW)

(21) Appl. No.: 14/244,948

(22) Filed: Apr. 4, 2014

(30) Foreign Application Priority Data
Oct. 23, 2013 (TW) 102138230

(51) Int. Cl. H03L 7/085

(52) U.S. Cl. CPC H03L 7/085
USPC 331/16

(57) ABSTRACT

A process, voltage, and temperature compensated oscillator, formed on an integrate circuit implemented by a semiconductor process, receives a supply voltage and includes: a variation bias unit provided with a variation bias output terminal and generating a process, voltage, and temperature compensated signal; a controlled oscillating unit provided with a control input terminal and an oscillating output and determining a signal oscillating frequency at the oscillating output terminal according to a signal at the control input terminal; and a tuning unit provided with a tuning input terminal, a compensating input terminal, a control output terminal, and a variable-parameter element, wherein the variable-parameter element includes a parameter and is coupled to the control output terminal, and the tuning unit determines the parameter according to a signal at the variation bias output terminal and a voltage signal or a digital signal received at the tuning input terminal.

### CROSS REFERENCE TO RELATED APPLICATIONS

This non-provisional application claims priority under 35 U.S.C. §119(a) on Patent Application No. 102138230 filed in Taiwan, R.O.C. on Oct. 23, 2013, the entire contents of which are hereby incorporated by reference herein.

### BACKGROUND OF THE INVENTION

1. Field of the Invention

The present invention relates to a process, voltage and temperature compensated oscillator and, more particularly, to a voltage or digitally controlled oscillator formed on a semiconductor integrated circuit.

2. Description of Related Art

An oscillator is a circuit that produces a clock signal for use in synchronizing circuit's operation and therefore the oscillator plays an indispensable role in the design of a communication system. As the techniques of the semiconductor process advance rapidly, many components of the communication system have been assembled and implemented on an integrated circuit, which meets manufacturing requirements of low costs, fast production, and miniaturization for communicating devices so that the communicating devices are made widely accessible in our daily life. Therefore, a single chip of integrated circuits that incorporates the oscillator component has become a trend in the design of the communication systems, as we already saw in most of existing consumer products.

Among a wide variety of oscillators, a voltage controlled oscillator (VCO) and a digitally controlled oscillator (DCO) provide an output of clock signal that is adjustable, and therefore either of the oscillators can be applied in a phase-locked loop (PLL) circuit for clock-data recovery or be configured to filter a clock signal having larger noise so as to output a clock signal with better signal-to-noise ratio (SNR). If an integrated circuit for VCO or DCO is to be implemented by the current semiconductor process, however, some limiting conditions must be considered and hold. First, semiconductor process variation can incur offsets in the parameters of semiconductor elements; for example, P-type transistors and N-type transistors may have respective regions for fast and slow variations. Second, the listed supply voltage provided to the circuit may have an allowable range of ±10% variation. Further, an application-dependent high-low temperature region may be imposed on the operating temperature for the circuit. With consideration of the limiting conditions, the maximum in the range of variation of the oscillator gain (i.e., the gain of the output signal frequency in response to the input signal of the oscillator) of a VCO or a DCO may be more than four times over the minimum in the range of variation. When this type of oscillator is applied in a PLL circuit, some of the units in the circuit, such as a loop filter, must be tolerant enough of parameter adjustment, that is, more elements as well as some extra adjustment circuit should be added in the PLL circuit, in order to accommodate possible range of variation of the oscillator gain, and thus the area of integrated circuits may increase, which raises costs, and the parasitic effect on the integrated circuits may becomes more prominent, thereby affecting operation speed and bandwidth limit of the circuits. Moreover, the gain of the noise path may increase as the oscillator gain becomes larger due to gain variation, and the accidentally increased noise will inevitably affect the SNR performance of the circuit.

To cope with the problems mentioned, prior-art designs of VCO or DCO are aimed at minimizing the range of variation of the oscillator gain. Conventional compensation methods for gain variation are divided into two categories, digital-type and analog-type, both of which obtain the range of variation for process parameter to provide a compensation for the bias voltage or the bias current, either of which is required by an oscillator. Such compensation methods, however, may be so complicated in terms of structure that it is possible to introduce a source of noise. Moreover, in prior-art compensation methods, the structural difference between the oscillator circuit and the compensation circuit is rather prominent that the variation correlation between the circuits is not significant, where the variation correlation is caused by processes, supply voltages, and temperature changes. That is, even the compensation methods provide a good compensation for the bias voltage or the bias current, the object to minimize the range of variation of the oscillator gain is not necessarily achievable. Besides, such compensation methods may require some extra circuit, such as a band-gap reference (BGR) circuit and a comparator, in order to provide specific operations and a base point for comparison. If implemented by current design methodology and semiconductor process, an additional process step may be required for the BGR circuit, and thus increase costs and the area of the integrated circuit. Moreover, the digital-type compensation method for gain variation usually lacks the function of tracking temperature changes in real-time; in addition, this type of method may require an additional digital algorithm when applied in a PLL application, a requirement which certainly increases the PLL locking time.

### BRIEF SUMMARY OF THE INVENTION

In view of the aforementioned problems, the present invention provides a process, voltage, and temperature compensated oscillator, implemented on an integrated circuit, for minimizing the range of variation of the oscillator gain.

The present invention provides a process, voltage, and temperature compensated oscillator, which is formed on an integrated circuit implemented by a semiconductor process and receives a supply voltage. The process, voltage, and temperature compensated oscillator is either a VCO or a DCO and includes a variation bias unit, a controlled oscillating unit, and a tuning unit.

The variation bias unit includes a variation bias output terminal. The variation bias output terminal outputs a compensated signal based on at least one from the changes consisting of the parameter offset, the supply voltage, and the operating temperature for the circuit, any of which is caused by the process variation of the semiconductor process. The controlled oscillating unit includes a control input terminal and an oscillating output terminal. The controlled oscillating unit determines the signal oscillating frequency at the oscillating output terminal according to the signal at the control input terminal. The tuning unit includes a tuning input terminal, a compensating input terminal, a control output terminal, and a variable-parameter element, where the compensating input terminal is coupled to the variation bias output terminal, and the control output terminal is coupled to the control input terminal of the controlled oscillating unit. The variable-parameter element is coupled to the control output terminal, where the variable-parameter element contains a parameter and the tuning unit determines the parameter according to the signal at the compensating input terminal and the voltage signal or the digital signal received at the tuning input terminal. The oscillating parameter associated with the elements inside the controlled oscillating unit, which is related to the oscillating parameter associated with the elements inside the variation bias unit, is used to determine the oscillator gain of the signal oscillating frequency at the oscillating output terminal in response to the signal at the tuning input terminal. The signal change at the control output terminal of the tuning unit, which is caused by the signal change at the variation bias output terminal, compensates for the offset of the oscillating parameter so as to minimize the range of variation of the oscillator gain.

The present invention provides another process, voltage, and temperature compensated oscillator, which is formed on an integrated circuit implemented by a semiconductor and receives a supply voltage. The process, voltage, and temperature compensated oscillator is either a VCO or a DCO and includes a variation bias unit, a tuning unit, and a controlled oscillating unit.

The variation bias unit includes a variation bias output terminal. The variation bias output terminal outputs a compensated signal based on at least one from the changes consisting of the parameter offset, the supply voltage, and the operating temperature for the circuit, any of which is caused by the process variation of the semiconductor process. The tuning unit includes a tuning input terminal, a control output terminal, and a variable-parameter element. The variable-parameter element is coupled to the control output terminal and the tuning input terminal, where the variable-parameter element contains a parameter and the tuning unit determines the parameter according to the voltage signal or the digital signal received at the tuning input terminal. The controlled oscillating unit includes a control input terminal, a compensating input terminal, and an oscillating output terminal. The control input terminal is coupled to the control output terminal and the compensating input terminal is coupled to the variation bias output terminal. The signal oscillating frequency at the oscillating output terminal is determined by the signal at the compensating input terminal and the parameter. The oscillating parameter associated with the elements inside the controlled oscillating unit, which is related to the oscillating parameter associated with the elements inside the variation bias unit, is used to determine the oscillator gain of the signal oscillating frequency at the oscillating output terminal in response to the signal at the tuning input terminal. The signal change at the variation bias output terminal compensates for the offset of the oscillating parameter so as to minimize the range of variation of the oscillator gain.

The present invention provides still another process, voltage, and temperature compensated oscillator, which is formed on an integrated circuit implemented by a semiconductor process and receives a supply voltage. The process, voltage, and temperature compensated oscillator is either a VCO or a DCO and includes a variation bias unit, a tuning unit, a controlled oscillating unit, and a compensation bias unit.

The variation bias unit includes a variation bias output terminal. The variation bias output terminal outputs a compensated signal based on at least one from the changes consisting of the parameter offset, the supply voltage, and the operating temperature for the circuit, any of which is caused by the process variation of the semiconductor process. The tuning unit includes a tuning input terminal, a control output terminal, and a variable-parameter element. The variable-parameter element is coupled to the control output terminal and contains a parameter, where the tuning unit determines the parameter of the variable-parameter element according to the voltage signal or the digital signal received at the tuning input terminal. The controlled oscillating unit includes a control input terminal, a variation reference terminal, a compensating input terminal, and an oscillating output terminal. The control input terminal is coupled to the control output terminal. The controlled oscillating unit determines the signal oscillating frequency at the oscillating output terminal according to the signal at the control input terminal and the parameter. The oscillating parameter associated with the elements inside the controlled oscillating unit, which is related to the oscillating parameter associated with the elements inside the variation bias unit, is used to determine the oscillator gain of the signal oscillating frequency at the oscillating output terminal in response to the signal at the tuning input terminal. The variation reference terminal outputs a reference signal according to the signal at the compensating input terminal and the oscillating parameter. The compensation bias unit includes a first input terminal coupled to the variation bias output terminal, a second input terminal coupled to the variation reference terminal, and a compensating output terminal coupled to the compensating input terminal. The compensation bias unit determines the output signal at the compensating output terminal by comparing the signal at the first input terminal with the signal at the second input terminal so as to compensate for the offset of the oscillating parameter and thus minimize the range of variation of the oscillator gain.

The advantageous effect of the present invention with reference to the prior art is that the variation bias unit of the present invention includes the same internal elements as the controlled oscillating unit and produces an output of variation bias based on at least one from the changes consisting of the parameter offset, the supply voltage, and the operating temperature for the circuit, with respect to the elements, so as to compensate the elements controlling the oscillator for the aspects of process, voltage, and temperature, thereby minimizing the range of variation of the oscillator gain.

### BRIEF DESCRIPTION OF THE SEVERAL VIEWS OF DRAWINGS

The structure as well as a preferred mode of use, further objects, and advantages of the present invention will be best understood by referring to the following detailed description of some illustrative embodiments in conjunction with the accompanying drawings, in which:

FIG. 1 is a schematic drawing of a process, voltage, and temperature compensated oscillator according to the first embodiment of the present invention;

FIG. 2 is a schematic drawing of a process, voltage, and temperature compensated oscillator according to the second embodiment of the present invention;

FIG. 3 is a schematic drawing of a process, voltage, and temperature compensated oscillator according to the third embodiment of the present invention;

FIG. 4 is a schematic drawing of a process, voltage, and temperature compensated oscillator according to the fourth embodiment of the present invention;

FIG. 5 is a schematic drawing of a process, voltage, and temperature compensated oscillator according to the fifth embodiment of the present invention;

FIG. 6 is a schematic drawing of a process, voltage, and temperature compensated oscillator according to the sixth embodiment of the present invention; and

FIG. 7 is a schematic drawing of a process, voltage, and temperature compensated oscillator according to the seventh embodiment of the present invention.

### DETAILED DESCRIPTION OF THE PREFERRED EMBODIMENTS

In the description hereinafter, the term of “coupled” or “coupling” refers to any two objects directly or indirectly electrically connected to each other. Therefore, if it is described that “a first device is coupled to a second device,” the meaning is that the first device is either directly electrically connected to the second device or indirectly electrically connected to the second device through other devices or connection means.

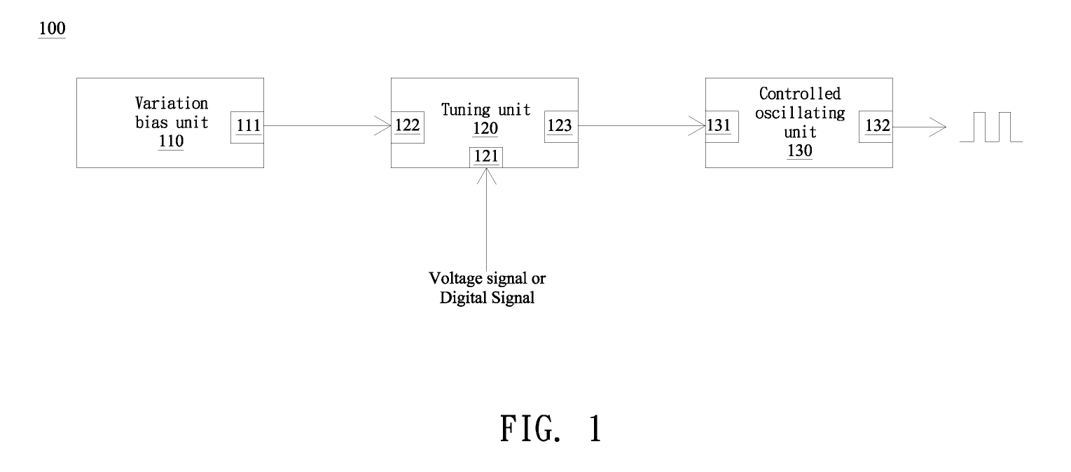

FIG. 1 shows a process, voltage, and temperature compensated oscillator according to the first embodiment of the present invention. The process, voltage, and temperature compensated oscillator 100 is formed on an integrated circuit implemented by a semiconductor process and receives a supply voltage. The process, voltage, and temperature compensated oscillator 100 is either a VCO or a DCO and includes a variation bias unit 110, a tuning unit 120, and a controlled oscillating unit 130.

As indicated in FIG. 1, the variation bias unit 110 is provided with a variation bias output terminal 111, where the variation bias output terminal 111 outputs a compensated signal based on at least one from the changes consisting of the parameter offset, the supply voltage, and the operating temperature for the circuit, any of which is caused by the process variation of the semiconductor process. The controlled oscillating unit 130 is provided with a control input terminal 131 and an oscillating output terminal 132, where the controlled oscillating unit 130 determines the signal oscillating frequency at the oscillating output terminal 132 according to the signal at the control input terminal 131. The tuning unit 120 is provided with a tuning input terminal 121, a compensating input terminal 122, a control output terminal 123, and a variable-parameter element, where the compensating input terminal 122 is coupled to the variation bias output terminal 111 and the control output terminal 123 is coupled to the control input terminal 131 of the controlled oscillating unit 130. The variable-parameter element is coupled to the control output terminal 123, where the variable-parameter element contains a parameter and the tuning unit 120 determines the parameter according to the signal at the compensating input terminal 122 and the voltage signal or the digital signal received at the tuning input terminal 121.

The oscillating parameter associated with the elements inside the controlled oscillating unit 130, which is related to the oscillating parameter associated with the elements inside the variation bias unit 110, is used to determine the oscillator gain of the signal oscillating frequency at the oscillating output terminal 132 in response to the signal at the tuning input terminal 121. The signal change at the control output terminal 123 of the tuning unit 120, which is caused by the signal change at the variation bias output terminal 111, compensates for the offset of the oscillating parameter so as to minimize the range of variation of the oscillator gain.

In the example the controlled oscillating unit 130 contains a transistor. The trans-conductance parameter of the transistor, controlled by the signal at the control input terminal 131, is used to determine the oscillator gain. The variation bias unit 110 contains another transistor, which is of the same type as in the controlled oscillating unit 130. The trans-conductance of the transistor is used to determine the signal at the variation bias output terminal 111. As the trans-conductance of the transistors of the controlled oscillating unit 130 and the variation bias unit 110 is increasing, a change which is caused by the process variation of the semiconductor process (e.g., the element is getting faster), the change of the supply voltage (e.g., the voltage is increasing), or the change of the operating temperature for the circuit (e.g., the temperature is getting lower), the signal at the variation bias output terminal 111 is changing accordingly, and the change causes a signal change at the control output terminal 123, which results in a recovery of trans-conductance of the transistor of the controlled oscillating unit 130 due to the signal adjustment of the control input terminal 131. Because the recovery of trans-conductance approaches to its original value, the variation range of the oscillator gain is thus reduced. Moreover, by changing the parameter of the variable-parameter element, a signal change of the voltage or digital signal received at the tuning input terminal 121 causes a signal change at the control output terminal 123, leading to a change of signal oscillating frequency at the oscillating output terminal 132, which corresponds to the required function of a VCO or a DCO.

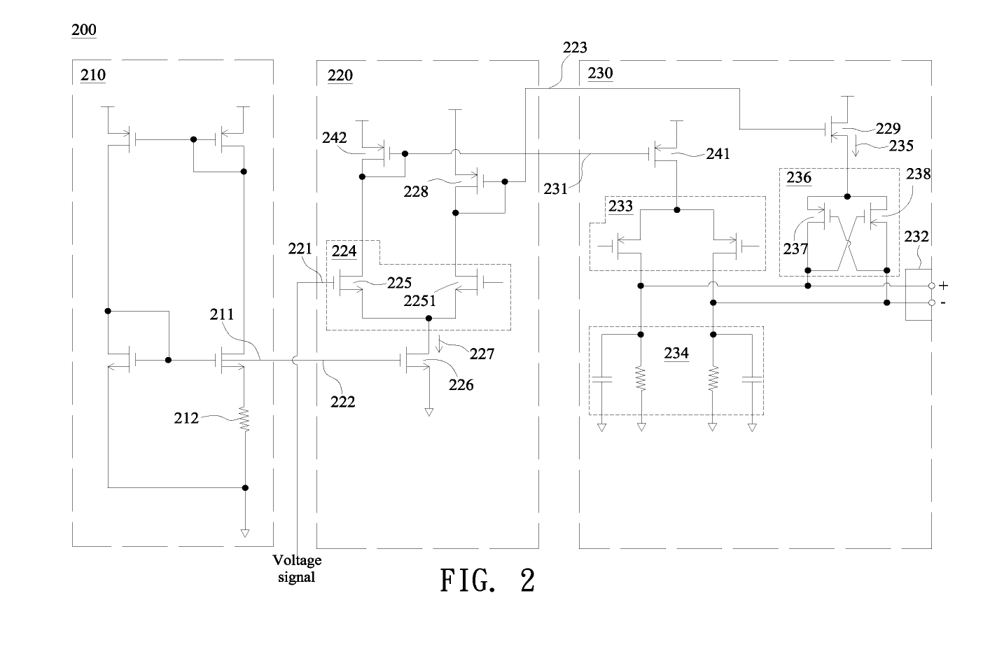

FIG. 2 shows a process, voltage, and temperature compensated oscillator according to the second embodiment of the present invention. The process, voltage, and temperature compensated oscillator 200 is formed on an integrated circuit implemented by a semiconductor process and receives a supply voltage. The process, voltage, and temperature compensated oscillator 200 is a VCO and includes a variation bias unit 210, a tuning unit 220, and a controlled oscillating unit 230.

As indicated in FIG. 2, the variation bias unit 210 includes a constant trans-conductance circuit having a resistor 212. The constant trans-conductance circuit includes a transistor, the trans-conductance of which is related to an oscillating parameter, and the trans-conductance of the transistor is changed according to the changes of the supply voltage and operating temperature for the circuit. The change of trans-conductance further causes the variation bias output terminal 211 to output a compensated signal.

The tuning unit 220 includes a tuning input terminal 221, a compensating input terminal 222, a control output terminal 223, a tuning differential input pair 224, differential transistors 225 and 2251, and a tuning current generator 226. The tuning differential input pair 224 is composed of the differential transistors, where one terminal of the channel of the differential transistor 2251 is coupled to the control output terminal 223. The gate or base of the differential transistor 2251 is coupled to a reference voltage, and the gate or base of the other differential transistor 225 is coupled to the tuning input terminal 221. The differential transistor 2251 has its own trans-conductance. The tuning current generator 226 is coupled to the compensating input terminal 222 and the tuning differential input pair 224 so as to generate a tuning bias current 227. The signal at the compensating input terminal 222 is used to determine the tuning bias current 227 which runs through the turning differential input pair 224. The tuning unit 220 determines the trans-conductance of the differential transistor 2251 according to the signal at the variation bias output terminal 221 as well as the voltage signal received at the tuning input terminal 221.

The controlled oscillating unit 230 includes a control input terminal 231, an oscillating output terminal 232, an oscillating differential input pair 233, an active load circuit 236, and a resistor-capacitor load 234. The controlled oscillating unit 230 includes a circuit having a ring oscillator structure by which an oscillating signal with oscillating frequency is generated. The oscillating differential input pair 233 is composed of transistors, and the output terminal of the oscillating differential input pair 233 forms the oscillating output terminal 232. The resistor-capacitor load 234 is coupled to the oscillating differential input pair 233 and forms a part of the load of the oscillating differential input pair 233. The active load circuit 236, which is composed of transistors, is coupled to the oscillating output terminal 232 and forms the other part of the load of the oscillating differential input pair 233. For example, the active load circuit 236 may include transistors 237 and 238, where one terminal of the channel of the transistor 237 is coupled to one terminal of the channel of the transistor 238 and the gate or base of the transistor 237 is coupled to the other terminal of the channel of the transistor 238 and one terminal of the oscillating output terminal 232, and where the gate or base of the transistor 238 is coupled to the other terminal of the channel of the transistor 237 and the other terminal of the oscillating output terminal 232. Such connection forms a positive feedback between the transistor 237 and the transistor 238 and provides an equivalent negative resistor, which is connected to the resistor-capacitor load 234 in parallel, at the oscillating output terminal 232. The signal oscillating frequency at the oscillating output terminal 232 is determined by the trans-conductance of the transistor of the active load circuit 236 and the resistance and the capacitance of the resistor-capacitor load 234. The oscillating differential input pair 233, the active load circuit 236, and the resistor-capacitor load 234 form a stage of the ring oscillator, and therefore the output oscillating frequency at the oscillating output terminal 232 can be changed by controlling the trans-conductance of the transistor of the active load circuit 236. The current 235 running through the active load circuit 236 can be determined by the effect of the current mirror, which is formed by the current of the differential transistor 2251 of the tuning unit 220 running through the transistors 228 and 229, where the current mirror is coupled to the tuning differential input pair 224 and the active load circuit 236, that is, the current running through the active load circuit 236 is proportional to the current running through the differential transistor 2251. Moreover, the bias current required for the oscillating differential input pair 233 is provided either by a fixed current source at the transistor 241 or by a current mirror formed by the coupling of the transistor 241 and the transistor 242 via the control input terminal 231 so as to provide further compensation for the trans-conductance of the transistor of the oscillating differential input pair 233. The transistor 242 is coupled to the one terminal of the channel of the differential transistor 225 such that the current running through the oscillating differential input pair 233 is proportional to the current running through the differential transistor 225.

Furthermore, the oscillating parameter (i.e., the trans-conductance of the transistor) associated with the element (i.e., the active load circuit 236) inside the controlled oscillating unit 230, which is related to the oscillating parameter associated with the element (i.e., the constant trans-conductance circuit) inside the variation bias unit 210, is used to determine the oscillator gain of the signal oscillating frequency at the oscillating output terminal 232 in response to the signal at the tuning input terminal 221. The signal change at the control output terminal 223 caused by the signal change at the variation bias output provides a compensation for the offset of the oscillating parameter and thereby reduces the range of variation of the oscillator gain.

For example, the trans-conductance gm of the transistor of the constant trans-conductance circuit is related, based on a first-order analysis, to the resistance Rb of the resistor 212 in terms of the following equation:

$$gm = \frac{1}{Rb}$$

As indicated in the equation, the trans-conductance gm is only dependent on, or proportional to, the resistance Rb. Therefore, if the process variation, voltage coefficient, and temperature coefficient of the resistance Rb are not considered, the change of trans-conductance gm is, generally, not dependent on the change of the parameter offset, the supply voltage, or the operating temperature for the circuit. In addition, the relationship among the constant trans-conductance circuit, the tuning current generator 226, the tuning differential input pair 224, the current mirror formed by the transistor 228, and the transistor 229, and the active load circuit 236 maintains a certain proportion between the trans-conductance of the transistor of the active load circuit 236 and the trans-conductance gm of the transistor of the constant trans-conductance circuit. Therefore, the change of the trans-conductance of the transistor of the active load circuit 236 is not dependent on the change of the parameter offset, the supply voltage, or the operating temperature, thereby minimizing the range of variation of the oscillator gain.

For example, the trans-conductance of a transistor may tend to be greater than the standard value if there is a change on the element (e.g., the transistor is getting faster), the supply voltage (e.g., the voltage is getting higher), or the operating temperature for the circuit (e.g., the temperature is getting lower), either of which is due to the process variation of the semiconductor process. Such change results in a smaller output voltage at the variation bias output terminal 211, and the active load circuit 236 is affected accordingly, resulting in a smaller current. Therefore, the trans-conductance of the transistor of the active load circuit 236 approaches to its original value, that is, the trans-conductance is only related to the resistance Rb.

A change on the process variation, voltage coefficient, and temperature coefficient of the resistance Rb may cause a change on the trans-conductance gm. However, because the process variation, voltage coefficient, and temperature coefficient of the resistance are well controlled by the present semiconductor process, any of these factors, if changed, has little effect on the resistance. Alternatively, the resistance can be well controlled by the resistors externally connected.

Further, the input voltage of the tuning input terminal 221 needs to be changed in order to control the output oscillating frequency of the VCO 200. That is, when the input voltage of the tuning input terminal 221 is getting smaller, the current running through the differential transistor 2251 increases, causing an increase on the current 235. Therefore, when the trans-conductance of the transistor of the active load circuit 236 is increasing, the equivalent negative resistance decreases, causing a decrease on the signal oscillating frequency at the oscillating output terminal 232, and vice versa.

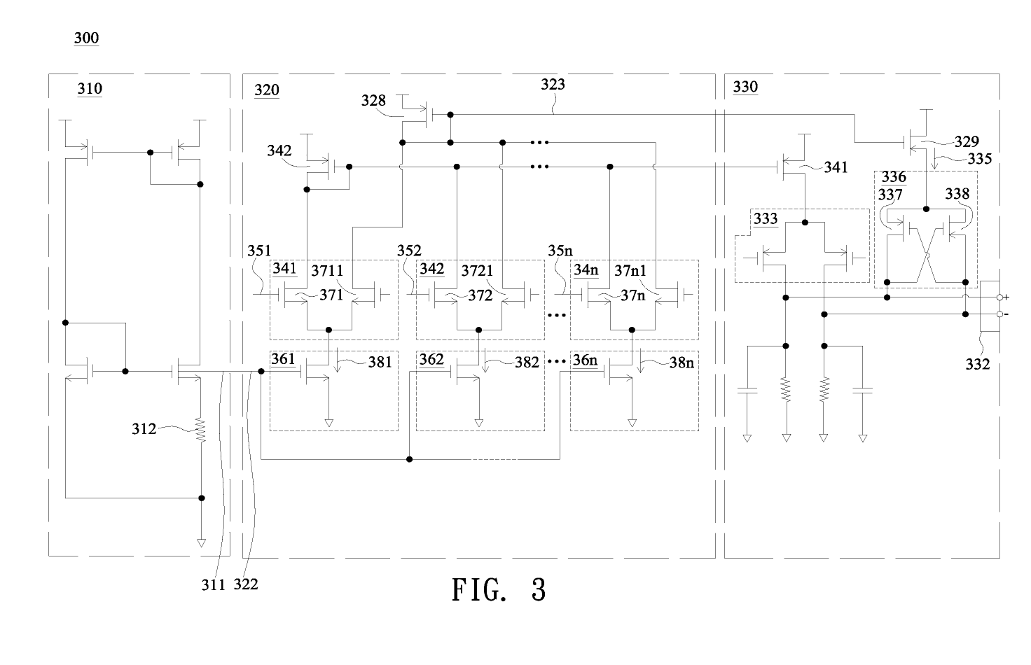

FIG. 3 shows a process, voltage, and temperature compensated oscillator according to the third embodiment of the present invention. The process, voltage, and temperature compensated oscillator 300 is formed on an integrated circuit implemented by a semiconductor process and receives a supply voltage. The process, voltage, and temperature compensated oscillator 300 is a DCO and includes a variation bias unit 310, a tuning unit 320, and a controlled oscillating unit 330.

As indicated in FIG. 3, the variation bias unit 310 includes a constant trans-conductance circuit having a resistor 312. The constant trans-conductance circuit includes a transistor, the trans-conductance of which is related to an oscillating parameter, and the trans-conductance is changed according to the changes of the supply voltage and operating temperature for the circuit. The change of trans-conductance further causes the variation bias output terminal 311 to output a compensated signal.

The tuning unit 320 includes digital tuning input terminals 351, 352, . . . , 35n, a compensating input terminal 322, a control output terminal 323, tuning differential input pairs 341, 342, . . . , 34n, differential transistors 371, 372, . . . , 37n, differential transistors 3711, 3721, . . . , 37n1, and tuning current generators 361, 362, . . . , 36n. The tuning differential input pairs 341, 342, . . . , 34n are individually composed of a pair of differential transistors. Each of the channels of the respective differential transistors 3711, 3721, . . . , 37n1 has one terminal coupled to the control output terminal 323. The corresponding gates or bases of the differential transistors 3711, 3721, . . . , 37n1 are separately coupled to a reference voltage. The corresponding gates or bases of the differential transistors 371, 372, . . . , 37n are coupled to the tuning input terminal 351, 352, . . . , 35n respectively, and the differential transistors 3711, 3721, . . . , 37n1 have its own trans-conductance. The tuning current generators 361, 362, . . . , 36n are jointly coupled to the compensating input terminal 322 and coupled to the tuning differential input pairs 341, 342, . . . , 34n respectively, so as to generate the tuning bias current 381, 382, . . . , 38n respectively. The signal at the compensating input terminal 322 determines the magnitude of the tuning bias currents 381, 382, . . . , 38n, and the tuning bias currents 381, 382, . . . , 38n run through the tuning differential input pairs 341, 342, . . . , 34n respectively. The tuning unit 320 determines the trans-conductance of the respective differential transistors 3711, 3721, . . . , 37n1 according to the signal of the variation bias output terminal 311 and the digital signals received by the tuning input terminals 341, 342, . . . , 34n.

For the controlled oscillating unit 330, the description can be referred to the description about the controlled oscillating unit 230 in the second embodiment of the present invention as shown in FIG. 2.

For example, the trans-conductance gm of the transistor of the constant trans-conductance circuit is related to, based on a first-order analysis, the resistance Rb of the transistor 312 in terms of the following equation:

$$gm = \frac{1}{Rb}$$

As indicated in the equation, the trans-conductance gm is only dependent on, or proportional to, the resistance Rb. Therefore, if the process variation, voltage coefficient, and temperature coefficient of the resistance Rb are not considered, the change of trans-conductance gm is, generally, not dependent on the change of the offset of the parameter, the supply voltage, or the operating temperature for the circuit. In addition, the relationship between the active load circuit 336 and the current mirror formed by the constant trans-conductance circuit, the tuning current generators 361, 362, . . . , 36n, the tuning differential input pairs 341, 342, . . . , 34n, the transistor 328, and the transistor 329 is fixed at a certain proportion between the trans-conductance of the transistor of the active load circuit 336 and the trans-conductance gm of the transistor of the constant trans-conductance circuit. Therefore, the change of the trans-conductance of the transistor of the active load circuit 336 is not dependent on the change of the offset of the parameter, the supply voltage, or the operating temperature, thereby reducing the range of variation of the oscillator gain resulting from the signal oscillating frequency in response to the signals of the tuning input terminals 351, 352, . . . , 35n.

For example, the trans-conductance of the transistor may tend to be greater than the standard value if there is a change on the element (e.g., the element is getting faster), the supply voltage (e.g., the voltage is getting higher), or the operating temperature for the circuit (e.g., the temperature is getting lower), either of which is due to the process variation of the semiconductor process. Such change results in a lower output voltage at the variation bias output terminal 311, and the active load circuit 336 is affected accordingly, resulting in a smaller current. Therefore, the trans-conductance of the transistor of the active load circuit 336 approaches to its original value, that is, the trans-conductance is only related to the resistance Rb.

A change on the process variation, voltage coefficient, and temperature coefficient of the resistance Rb may cause a change on the trans-conductance gm. However, because the process variation, voltage coefficient, and temperature coefficient of the resistance are well controlled by the present semiconductor process, any of these factors, if changed, has little effect on the resistance. Alternatively, the resistance can be well controlled by the resistors externally connected.

Furthermore, to control the output oscillating frequency of the DCO 300, the input digital values of the tuning input terminals 351, 352, . . . , 35n need to be changed such that the tuning bias currents 381, 382, . . . , 38n can select whether or not to run through the differential transistors 3711, 3721, . . . , 37n1, and the current running through the active load circuit 336 due to the current mirror formed by the transistors 328 and 329 has to be maintained proportional to the sum of the current running through each of the differential transistors 3711, 3721, . . . , 37n1. That is, when the digital input formed by the tuning input terminals 351, 352, . . . , 35n causes the sum of the current running through the differential transistors 3711, 3721, . . . , 37n1 to increase, the current 335 increases accordingly. Therefore, when the trans-conductance of the transistor of the active load circuit 336 is increasing, the equivalent negative resistance decreases, causing a decrease on the signal oscillating frequency of the oscillating output terminal 332, and vice versa.

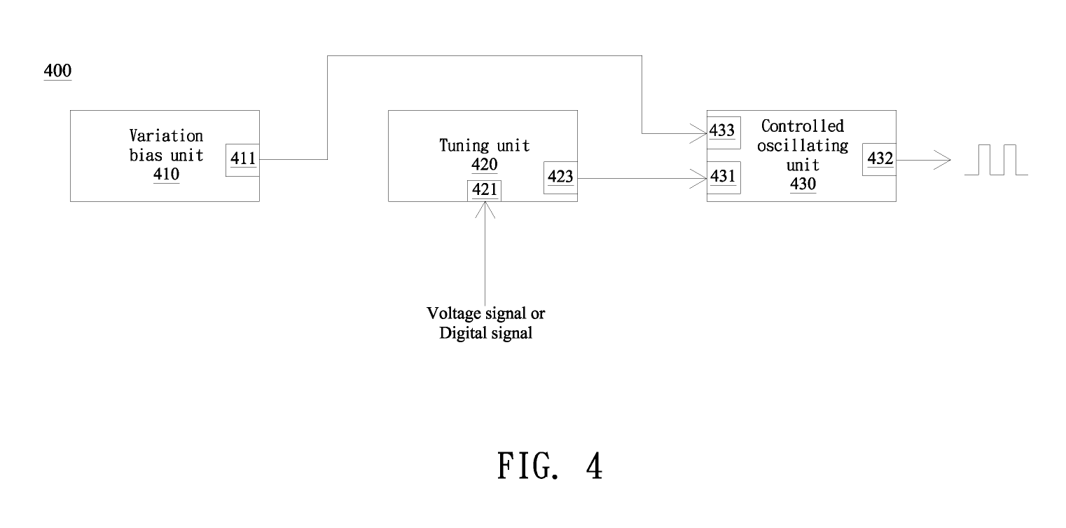

FIG. 4 shows a process, voltage, and temperature compensated oscillator according to the fourth embodiment of the present invention. The process, voltage, and temperature compensated oscillator 400 is formed on an integrated circuit implemented by a semiconductor process and receives a supply voltage. The process, voltage, and temperature compensated oscillator 400 is either a VCO or a DCO and includes a variation bias unit 410, a tuning unit 420, and a controlled oscillating unit 430.

As indicated in FIG. 4, the variation bias unit 410 is provided with a variation bias output terminal 411, where the variation bias output terminal 411 outputs a compensated signal based on at least one from the changes consisting of the parameter offset, the supply voltage, and the operating temperature for the circuit, any of which is caused by the process variation of the semiconductor process. The tuning unit 420 is provided with a tuning input terminal 421, a control output terminal 423, and a variable-parameter element, where the variable-parameter element contains a parameter and the tuning unit 420 determines the parameter according to the voltage signal or the digital signal received at the tuning input terminal 421. The controlled oscillating unit 430 is provided with a control input terminal 431, a compensating input terminal 433, and an oscillating output terminal 432, where the control input terminal 431 is coupled to the control output terminal 423 and the compensating input terminal 433 is coupled to the variation bias output terminal 411. The signal oscillating frequency at the oscillating output terminal 432 is determined by the signal at the compensating input terminal 433 and the parameter.

The oscillating parameter associated with the elements inside the controlled oscillating unit 430, which is related to the oscillating parameter associated with the elements inside the variation bias unit 410, is used to determine the oscillator gain of the signal oscillating frequency at the oscillating output terminal 432 in response to the signal at the tuning input terminal 421. The signal change at the variation bias output terminal 411 compensates for the offset of the oscillating parameter so as to minimize the range of variation of the oscillator gain.

In the example the controlled oscillating unit 430 contains a transistor. The trans-conductance parameter of the transistor, controlled by the signal at the compensating input terminal 433, is used to determine the oscillator gain. The variation bias unit 410 contains another transistor, which is of the same type as in the controlled oscillating unit 430, where the trans-conductance of the transistor is used to determine the signal at the variation bias output terminal 411. As the trans-conductance of the transistors of the controlled oscillating unit 130 and the variation bias unit 410 is increasing, a change which is caused by the process variation of the semiconductor process (e.g., the element is getting faster), the change of the supply voltage (e.g., the voltage is increasing), or the change of the operating temperature for the circuit (e.g., the temperature is getting lower), the signal at the variation bias output terminal 411 is changing accordingly, and the change causes a recovery of trans-conductance of the transistor of the controlled oscillating unit 430 due to the signal adjustment of the compensating input terminal 433. Because the recovery of trans-conductance approaches to its original value, the variation range of the oscillator gain is thus reduced. Moreover, by changing the parameter of the variable-parameter element, a change of the voltage or digital signal received at the tuning input terminal 421 causes a signal change at the control output terminal 423, leading to a change of signal oscillating frequency at the oscillating output terminal 432, which corresponds to the required function of a VCO or a DCO.

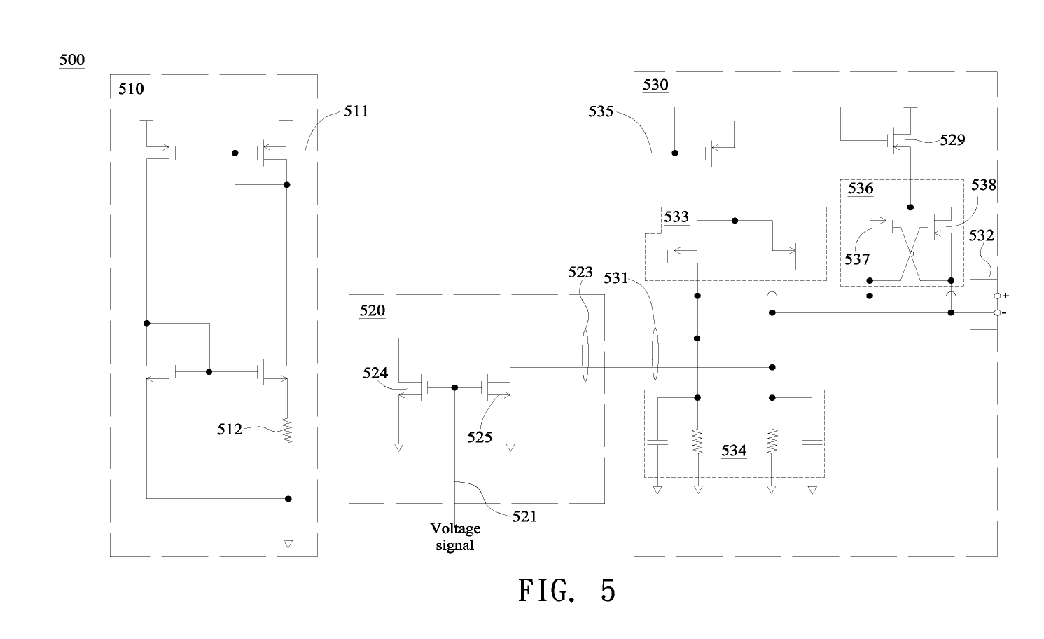

FIG. 5 shows a process, voltage, and temperature compensated oscillator according to the fifth embodiment of the present invention. The process, voltage, and temperature compensated oscillator 500 is formed on an integrated circuit implemented by a semiconductor process and receives a supply voltage. The process, voltage, and temperature compensated oscillator 500 is a VCO and includes a variation bias unit 510, a tuning unit 520, and a controlled oscillating unit 530.

As indicated in FIG. 5, the variation bias unit 510 includes a constant trans-conductance circuit having a resistor 512. The constant trans-conductance circuit includes a transistor, the trans-conductance of which is related to an oscillating parameter, and the trans-conductance of the transistor is changed according to the changes of the supply voltage and operating temperature for the circuit. The change of trans-conductance further causes the variation bias output terminal 511 to output a compensated signal.

The tuning unit 520 includes a tuning input terminal 521, a control output terminal 223, and tuning transistors 524 and 525. The tuning transistor 524 and the tuning transistor 525 are couple to the tuning input terminal 512 and the control output terminal respectively. The voltage signal received at the tuning input terminal 521 determines the equivalent resistor corresponding to the channel of the tuning transistors 524 and 525, that is, the tuning transistors 524 and 525 are used as a voltage controlled resistor. The tuning transistors 524 and 525 are coupled to the controlled oscillating unit 530 and are used as a load which is changeable by control.

The controlled oscillating unit 530 includes a control input terminal 531, an oscillating output terminal 532, an oscillating differential input pair 533, an active load circuit 536, a resistor-capacitor load 534, and a compensating input terminal 535. The controlled oscillating unit 530 includes a circuit having a ring oscillator structure by which an oscillating signal with oscillating frequency is generated. The oscillating differential input pair 533 is composed of transistors, and the output terminal of the oscillating differential input pair 533 forms the oscillating output terminal 532. The resistor-capacitor load 534 is coupled to the oscillating differential input pair 533 and forms a part of the load of the oscillating differential input pair 533. The active load circuit 536, which is composed of transistors, is coupled to the oscillating output terminal 532 and forms the other part of the load of the oscillating differential input pair 533. For example, the active load circuit 536 may include transistors 537 and 538, where one terminal of the channel of the transistor 537 is coupled to one terminal of the channel of the transistor 538 and the gate or base of the transistor 537 is coupled to the other terminal of the channel of the transistor 538 and one terminal of the oscillating output terminal 532, and where the gate or base of the transistor 538 is coupled to the other terminal of the channel of the transistor 537 and the other terminal of the oscillating output terminal 532. Such connection forms a positive feedback between the transistor 537 and the transistor 538 and provides an equivalent negative resistor, which is connected to the resistor-capacitor load 534 in parallel, at the oscillating output terminal 532. The signal oscillating frequency at the oscillating output terminal 532 is determined by the trans-conductance of the transistor of the active load circuit 536, the equivalent resistor of the channel of the tuning transistors 524 and 525, and the resistance and the capacitance of the resistor-capacitor load 534. The oscillating differential input pair 533, the active load circuit 536, and the resistor-capacitor load 534, and the tuning unit 520 form a stage of the ring oscillator, and therefore the output oscillating frequency at the oscillating output terminal 532 can be changed by controlling the trans-conductance of the transistor of the active load circuit 536 and the equivalent resistor of the channel of the tuning transistors 524 and 525.

For example, the trans-conductance gm of the transistor of the constant trans-conductance circuit is related to, based on a first-order analysis, the resistance Rb of the resistor 512 in terms of the following equation:

$$gm = \frac{1}{Rb}$$

As indicated in the equation, the trans-conductance gm is only dependent on, or proportional to, the resistance Rb. Therefore, if the process variation, voltage coefficient, and temperature coefficient of the resistance Rb are not considered, the change of trans-conductance gm is, generally, not dependent on the change of the parameter offset, the supply voltage, or the operating temperature for the circuit. In addition, the relationship among the constant trans-conductance circuit, the transistor 529, and the active load circuit 536 maintains a certain proportion between the trans-conductance of the transistor of the active load circuit 536 and the trans-conductance gm of the transistor of the constant trans-conductance circuit. Therefore, the change of the trans-conductance of the transistor of the active load circuit 536 is not dependent on the change of the parameter offset, the supply voltage, or the operating temperature, thereby minimizing the range of variation of the oscillator gain of the signal oscillating frequency at the oscillating output terminal 532 in response to the signal at the tuning input terminal 521.

For example, the trans-conductance of a transistor may tend to be greater than the standard value if there is a change on the element (e.g., the transistor is getting faster), the supply voltage (e.g., the voltage is getting higher), or the operating temperature for the circuit (e.g., the temperature is getting lower), either of which is due to the process variation of the semiconductor process. Such change results in an increased output voltage at the variation bias output terminal 511, and the active load circuit 536 is affected accordingly, resulting in a smaller current. Therefore, the trans-conductance of the transistor of the active load circuit 536 approaches to its original value, that is, the trans-conductance is only related to the resistance Rb.

A change on the process variation, voltage coefficient, and temperature coefficient of the resistance Rb may cause a change on the trans-conductance gm. However, because the process variation, voltage coefficient, and temperature coefficient of the resistance are well controlled by the present semiconductor process, any of these factors, if changed, has little effect on the resistance. Alternatively, the resistance can be well controlled by the resistors externally connected.

Further, the input voltage of the tuning input terminal 521 needs to be changed in order to control the output oscillating frequency of the VCO 500. That is, when the input voltage of the tuning input terminal 521 is getting smaller, the resistance of the equivalent resistor of the channel of the tuning transistors 524 and 525 is increasing, causing a decrease on the signal oscillating frequency at the oscillating output terminal 532, and vice versa.

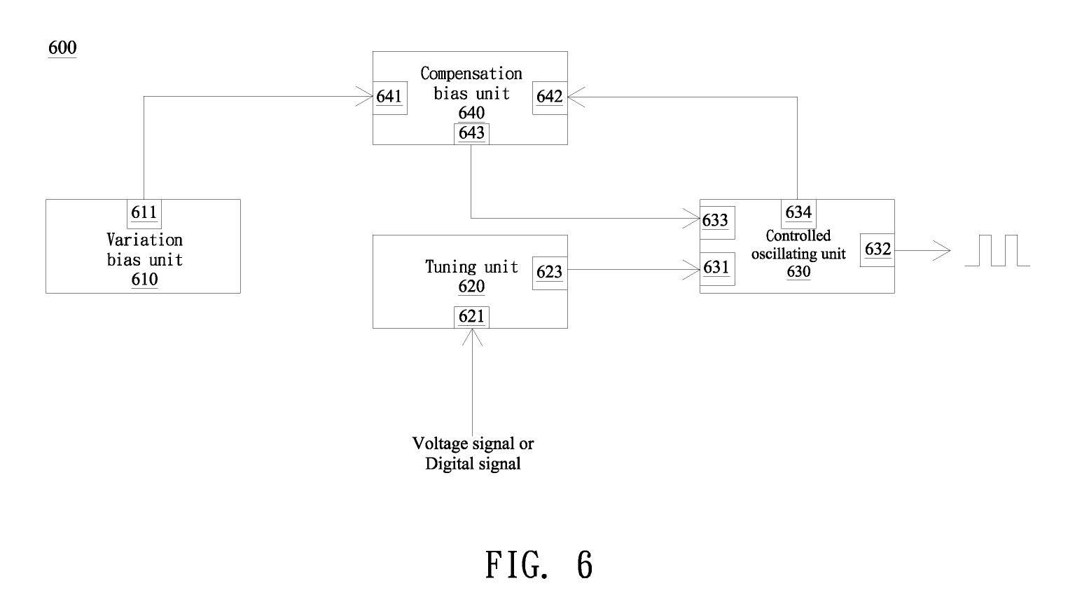

FIG. 6 shows a process, voltage, and temperature compensated oscillator according to the sixth embodiment of the present invention. The process, voltage, and temperature compensated oscillator 600 is formed on an integrated circuit implemented by a semiconductor process and receives a supply voltage. The process, voltage, and temperature compensated oscillator 600 is either a VCO or a DCO and includes a variation bias unit 610, a tuning unit 620, a controlled oscillating unit 630, and a compensation bias unit 640.

As indicated in FIG. 6, the variation bias unit 610 is provided with a variation bias output terminal 611, where the variation bias output terminal 611 outputs a compensated signal based on at least one from the changes consisting of the parameter offset, the supply voltage, and the operating temperature for the circuit, any of which is caused by the process variation of the semiconductor process. The tuning unit 620 is provided with a tuning input terminal 621, a control output terminal 623, and a variable-parameter element, where the variable-parameter element contains a parameter and the tuning unit 620 determines the parameter according to the voltage signal or the digital signal received at the tuning input terminal 621. The controlled oscillating unit 630 is provided with a control input terminal 631, a variation reference terminal 634, a compensating input terminal 633, and an oscillating output terminal 632. The controlled oscillating unit 630 determines the signal oscillating frequency at the oscillating output terminal 632 according to the signal at the control input terminal 631 and the parameter. The oscillating parameter associated with the elements inside the controlled oscillating unit 630, which is related to the oscillating parameter associated with the elements inside the variation bias unit 610, is used to determine the oscillator gain of the signal oscillating frequency at the oscillating output terminal 632 in response to the signal at the tuning input terminal 621. The variation reference terminal 634 outputs a reference signal according to the compensating input terminal 633 and the oscillating parameter. The compensation bias unit 640 is provided with a first input terminal 641 coupled to the variation bias output terminal 611, a second input terminal 642 coupled to the variation reference terminal 634, and a compensating output terminal 643 coupled to the compensating input terminal 633. The compensation bias unit 640 determines the output signal at the compensating output terminal 643 according to the comparison between the signal of the first input terminal 641 and the signal of the second input terminal 642, compensating for the offset of the oscillating parameter, so as to minimize the range of variation of the oscillator gain.

In the example the controlled oscillating unit 630 contains a transistor. The trans-conductance parameter of the transistor, controlled by the signal at the control input terminal 631 and the signal at the compensating input terminal 633, is the oscillating parameter for determining the oscillator gain. The variation bias unit 610 contains another transistor, which is of the same type as in the controlled oscillating unit 630, where the trans-conductance of the transistor is used to determine the output signal at the variation bias output terminal 611. As the trans-conductance of the transistors of the controlled oscillating unit 630 and the variation bias unit 610 is increasing, a change which is caused by the process variation of the semiconductor process (e.g., the element is getting faster), the change of the supply voltage (e.g., the voltage is increasing), or the change of the operating temperature for the circuit (e.g., the temperature is getting lower), the signal at the variation bias output terminal 611 is changing accordingly. If the compensation bias unit 640 detects that there is a change on the comparison between the signal at the first input terminal 641 and the signal at the second input terminal 642, for example, if the difference between the signals differs from a predetermined value, then the compensation bias unit 640 changes the compensating output terminal 643, which is then input to the compensating input terminal 633, so as to compensate for the change of the trans-conductance of the transistor in the controlled oscillating unit 630, and the variation reference terminal 634 sends a feedback signal to the second input terminal 642 in response to the change, until the difference between first input terminal 641 and the second input terminal 642 returns to its predetermined value. Such change causes a recovery of trans-conductance of the transistor of the controlled oscillating unit 630 due to the signal adjustment of the compensating input terminal 633. Because the recovery of trans-conductance approaches to its original value, the variation range of the oscillator gain is thus reduced. Moreover, by changing the parameter of the variable-parameter element, a change of the voltage or digital signal received at the tuning input terminal 621 causes a signal change at the control output terminal 623, leading to a change of signal oscillating frequency at the oscillating output terminal 632, which corresponds to the required function of a VCO or a DCO.

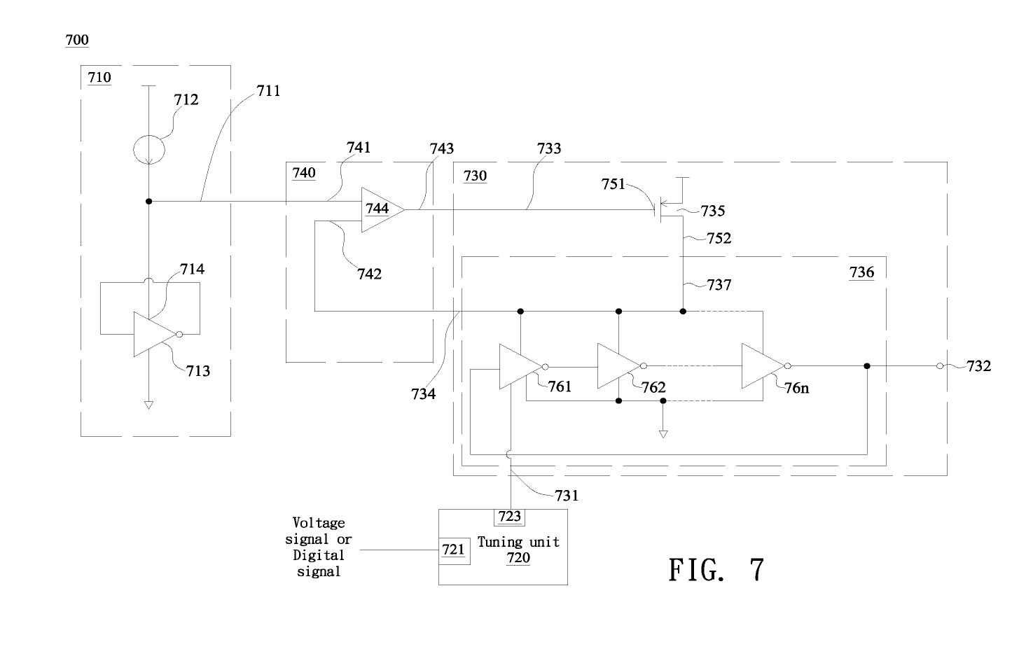

FIG. 7 shows a process, voltage, and temperature compensated oscillator according to the seventh embodiment of the present invention. The process, voltage, and temperature compensated oscillator 700 is formed on an integrated circuit implemented by a semiconductor process and receives a supply voltage. The process, voltage, and temperature compensated oscillator 700 is a VCO and includes a variation bias unit 710, a tuning unit 720, a controlled oscillating unit 730, and a compensation bias unit 740.

As indicated in FIG. 7, the variation bias unit 710 is provided with a variation bias output terminal 711, a fixed current source 712, and an inverter 713. The fixed current source 712 and the supply voltage terminal 714 of the inverter 713 are coupled to the variation bias output terminal 711, and the input terminal of the inverter 713 is coupled to its output terminal. The fixed current source 712 is used to output a fixed current having process, voltage, and temperature compensated characteristics. The variation bias output terminal 711 outputs a compensated signal based on at least one from the changes consisting of the parameter offset, the supply voltage, and the operating temperature for the circuit, any of which is caused by the process variation of the semiconductor process.

The tuning unit 720 is provided with a tuning input terminal 721, a control output terminal 723, and a variable-parameter element, where the variable-parameter element contains a parameter and the tuning unit 720 determines the parameter according to the voltage signal or the digital signal received at the tuning input terminal 721.

The controlled oscillating unit 730 is provided with a control input terminal 731, a variation reference terminal 734, a compensating input terminal 733, an oscillating output terminal 732, a current generator 735, and a ring oscillator 736. The current generator 735 is a transistor having a control terminal 751 and a current output terminal 752. The control terminal 751 is coupled to the compensating input terminal 733. The current output terminal 752 is coupled to the supply voltage terminal 737 of the ring oscillator 736 and forms the variation reference terminal 734. The current generator 735 determines the output current at the current output terminal 752 according to the signal at the control terminal 751. The ring oscillator 736 is composed of inverters 761, 762, . . . , 76n connected to each other in series. The inverter 761 is coupled to the control input terminal 731 to correspond to the required function of a VCO or a DCO. Alternatively, the ring oscillator 736 is composed of multiple delay cells (not shown in FIG. 7) connected in series, and each of the multiple delay cells of the ring oscillator 736 is coupled to the control input terminal 731 to correspond to the required function of a VCO or a DCO.

The compensation bias unit 740 is provided with a first input terminal 741, a second input terminal 742, a compensating output terminal 743, and a differential amplifier 744. The first input terminal 741 is an input terminal of the differential amplifier 744 and is coupled to the variation bias output terminal 711. The second input terminal 742 is the other input terminal of the differential amplifier 744 and is coupled to the variation reference terminal 734. The compensating output terminal 743 is the output terminal of the differential amplifier 744 and is coupled to the compensating input terminal 733. The compensation bias unit 740 compares the signal at the first input terminal 741 with the signal at the second input terminal 742, based on the negative feedback loop formed by the connection between the differential amplifier 744 and the current generator 735, so as to determine the output signal at the compensating output terminal 743, maintaining a substantially equal voltage at the first input terminal 741 and the second input terminal 742, and thereby compensate for the parameter offset of the controlled oscillating unit 740.

In the example of the controlled oscillating unit 730, the output current from the current generator 735 determines each operating current of the inverters 761, 762, . . . , 76n of the ring oscillator 736, that is, the output current determines the trans-conductance of the transistor contained in the ring oscillator 736, and the trans-conductance parameter is directly related to the oscillator gain of the signal oscillating frequency of the oscillating output terminal 732 in response to the signal at the tuning input terminal 721. The variation bias unit 710 includes an inverter 714, which is of the same type as provided in the ring oscillator 736, for determining the output signal at the variation bias output terminal 711. As the trans-conductance of the transistors of the controlled oscillating unit 730 and the variation bias unit 710 is increasing, a change which is caused by the process variation of the semiconductor process (e.g., the element is getting faster), the change of the supply voltage (e.g., the voltage is increasing), or the change of the operating temperature for the circuit (e.g., the temperature is getting lower), the signal at the variation bias output terminal 711 is decreasing accordingly, causing the current generator 735 to output more current. The compensation bias unit 740 then detects that the signal state at the first input terminal 741 is different from its original value, that is, there exists a substantial difference between the first input terminal 741 and the second input terminal 742. Such change results in a larger signal output at the compensating output terminal 743, which is input to the compensating input terminal 733, and a decreasing current from the current generator 735, making the voltage of the variation reference terminal 734 smaller until the signal at the first input terminal 741 is substantially equal to the signal at the second input terminal 742. Such change causes a recovery of trans-conductance of the transistor of the controlled oscillating unit 730 due to the signal adjustment of the compensating input terminal 733. Because the recovery of trans-conductance approaches to its original value, the variation range of the oscillator gain is thus reduced.

Moreover, in an embodiment of the tuning unit 720, the variable-parameter element may be a variable capacitor. The variable capacitor is provided with a control terminal coupled to the tuning input terminal 721, where the signal at the control terminal determines the capacitance of the variable capacitor and one of the electrode terminals of the variable capacitor is coupled to the control output terminal 723. In another embodiment of the tuning unit 720, the variable-parameter element may be a digitally controlled current array having a control terminal coupled to the tuning input terminal 721. The digital signal of the control terminal determines the output current of the current array, the output terminal of which is coupled to the control input terminal 723, and the output current is provided to the inverter 761 for changing the trans-conductance of the transistor of the inverter 761. The above-mentioned embodiments of the tuning unit 720 should be known by persons ordinarily skilled in the art, and thus no further detail regarding the embodiments is provided herein. By changing the parameter of the variable-parameter element, a change of the voltage or digital signal received at the tuning input terminal 721 causes a signal change at the control output terminal 723 or at the load, leading to a change of signal oscillating frequency at the oscillating output terminal 732, which corresponds to the required function of a VCO or a DCO.

What is claimed is:

1. A process, voltage, and temperature compensated oscillator formed on an integrated circuit implemented by a semiconductor process, receiving a supply voltage and being either a voltage controlled oscillator (VCO) or a digitally controlled oscillator (DCO), said oscillator comprising:
a variation bias unit provided with a variation bias output terminal, said variation bias output terminal outputting a compensated signal based on at least one from the changes consisting of a parameter offset, said supply voltage, and an operating temperature for the circuit, wherein any of the changes is caused by a semiconductor process variation;
a controlled oscillating unit provided with a control input terminal and an oscillating output terminal, said controlled oscillating unit determining a signal oscillating frequency at said oscillating output terminal according to a signal at said control input terminal; and
a tuning unit provided with a tuning input terminal, a compensating input terminal, a control output terminal, and a variable-parameter element, said compensating input terminal being coupled to said variation bias output terminal, said control output terminal being coupled to said control input terminal, said variable-parameter element being coupled to said control output terminal, said variable-parameter element having an element parameter, said tuning unit determining said element parameter according to a signal at said compensating input terminal and a voltage signal or a digital signal received at said tuning input terminal;
wherein:
an oscillating parameter associated with elements inside said controlled oscillating unit is related to an oscillating parameter associated with elements inside said variation bias unit, and the oscillating parameter of said controlled oscillating unit is used to determine an oscillator gain of the signal oscillating frequency at said oscillating output terminal in response to the signal at said tuning input terminal; a signal change at said control output terminal of said tuning unit, which is caused by a signal change at said variation bias output terminal, compensates for the offset of said oscillating parameter so as to minimize the range of variation of said oscillator gain.

2. The oscillator of claim 1, further comprising:
a constant trans-conductance circuit forming said variation bias unit, having a transistor, wherein a trans-conductance of said transistor is related to said oscillating parameter, and said trans-conductance is changed according to the changes of said supply voltage and said operating temperature for the circuit, and wherein the change of said trans-conductance causes a signal change at said variation bias output terminal;
a tuning differential input pair provided in said tuning unit, being composed of differential transistors, wherein a first differential transistor of said tuning differential input pair is said variable-parameter element and one terminal of the channel of the first differential transistor is coupled to said control output terminal, and wherein the gate or the base of a second differential transistor of said tuning differential input pair is coupled to said tuning input terminal;
a tuning current generator coupled to said compensating input terminal and said tuning differential input pair, for generating a tuning bias current, wherein the signal at said compensating input terminal is used to determine said tuning bias current, and said tuning bias current runs through said tuning differential input pair; and
an active load circuit provided in said controlled oscillating unit, being composed of transistors having said oscillating parameter, wherein the current running through said active load circuit is proportional to the current running through the first differential transistor.

3. The oscillator of claim 1, further comprising:
a constant trans-conductance circuit forming said variation bias unit, having a transistor, wherein a trans-conductance of said transistor is related to the oscillating parameter, and said trans-conductance is changed according to the changes of said supply voltage and said operating temperature for the circuit, and wherein the change of said trans-conductance causes a signal change at said variation bias output terminal;
a plurality of digital input terminals forming said tuning input terminal;
at least one tuning differential input pair provided in said tuning unit, being composed of differential transistors, wherein a first differential transistor of each said tuning differential input pair is said variable-parameter element and one terminal of the channel of each the first differential transistor is coupled to said control output terminal, and wherein the gate or the base of a second differential transistor of each said tuning differential input pair is coupled to each digital input terminal of said tuning input terminal;
at least one tuning current generator coupled to said compensating input terminal and each said tuning differential input pair, for generating a respective tuning bias current, wherein the signal at said compensating input terminal determines each said tuning bias current, and each said tuning bias current, generated by said respective tuning current generator, runs through said respective tuning differential input pair; and
an active load circuit provided in said controlled oscillating unit, being composed of transistors having said oscillating parameter, wherein the current running through said active load circuit is proportional to the sum of current running through each the first differential transistor.

4. A process, voltage, and temperature compensated oscillator formed on an integrated circuit implemented by a semiconductor process, receiving a supply voltage and being either a voltage controlled oscillator (VCO) or a digitally controlled oscillator (DCO), said oscillator comprising:
a variation bias unit provided with a variation bias output terminal, said variation bias output terminal outputting a compensated signal based on at least one from the changes consisting of a parameter offset, said supply voltage, and an operating temperature for the circuit, wherein any of the changes is caused by a semiconductor process variation;
a tuning unit provided with a tuning input terminal, a control output terminal, and a variable-parameter element, said variable-parameter element being coupled to said control output terminal and said tuning input terminal, said variable-parameter element having an element parameter, said tuning unit determining said element parameter of said variable-parameter element according to a voltage signal or a digital signal received at said tuning input terminal; and
a controlled oscillating unit provided with a control input terminal, a compensating input terminal, and an oscillating output terminal, said control input terminal being coupled to said control output terminal, said compensating input terminal being coupled to said variation bias output terminal, said controlled oscillating unit determining a signal oscillating frequency at said oscillating output terminal according to a signal at said compensating input terminal and said element parameter;
wherein:
an oscillating parameter associated with elements inside said controlled oscillating unit is related to an oscillating parameter associated with elements inside said variation bias unit, and the oscillating parameter of said controlled oscillating unit is used to determine an oscillator gain of the signal oscillating frequency at said oscillating output terminal in response to the signal at said tuning input terminal; a signal change at said control output terminal of said tuning unit, which is caused by a signal change at said variation bias output terminal, compensates for the offset of said oscillating parameter so as to minimize the range of variation of said oscillator gain.

5. The oscillator of claim 4, further comprising:
a constant trans-conductance circuit forming said variation bias unit, having a transistor, wherein a trans-conductance of said transistor is related to said oscillating parameter, and said trans-conductance is changed according to the changes of said supply voltage and said operating temperature for the circuit, and wherein the change of said trans-conductance causes a signal change at said variation bias output terminal; and
an active load circuit provided in said controlled oscillating unit, being composed of transistors having said oscillating parameter, wherein the current running through said active load circuit is determined by the signal at said compensating input terminal.

6. The oscillator of claim 5, further comprising:
a voltage controlled resistor provided in said tuning unit, said voltage controlled resistor having a control terminal, wherein the control terminal is coupled to said tuning input terminal, and the voltage signal at said control terminal is used to determine the resistance of said voltage controlled resistor, and wherein one terminal of said voltage controlled resistor is coupled to said control output terminal.

7. The oscillator of claim 4, wherein said variable-parameter element of said tuning unit is a variable capacitor, said variable capacitor being provided with a control terminal, said control terminal being coupled to said tuning input terminal, wherein a signal at said control terminal is used to determine a capacitance of said variable capacitor, and one of the two electrode terminals of said variable capacitor is coupled to said control output terminal.

8. The oscillator of claim 5, wherein said variable-parameter element of said tuning unit is a variable capacitor, said variable capacitor being provided with a control terminal, said control terminal being coupled to said tuning input terminal, wherein a signal at said control terminal is used to determine a capacitance of said variable capacitor, and one of the two electrode terminals of said variable capacitor is coupled to said control output terminal.

9. A process, voltage, and temperature compensated oscillator formed on an integrated circuit implemented by a semiconductor process, receiving a supply voltage and being either a voltage controlled oscillator (VCO) or a digitally controlled oscillator (DCO), said oscillator comprising:
a variation bias unit provided with a variation bias output terminal, said variation bias output terminal outputting a compensated signal based on at least one from the changes consisting of a parameter offset, said supply voltage, and an operating temperature for the circuit, wherein any of which is caused by a semiconductor process variation;
a tuning unit provided with a tuning input terminal, a control output terminal, and a variable-parameter element, said variable-parameter element being coupled to said control output terminal, said variable-parameter element having a element parameter, said tuning unit determining said element parameter of said variable-parameter element according to a voltage signal or a digital signal received at said tuning input terminal;
a controlled oscillating unit provided with a control input terminal, a variation reference terminal, a compensating input terminal, and an oscillating output terminal, said control input terminal being coupled to said control output terminal, said controlled oscillating unit determining a signal oscillating frequency at said oscillating output terminal according to a signal at said compensating input terminal and said element parameter, wherein an oscillating parameter associated with elements inside said controlled oscillating unit is related to an oscillating parameter of elements inside said variation bias unit, and the oscillating parameter of said controlled oscillating unit is used to determine an oscillator gain of the signal oscillating frequency at said oscillating output terminal in response to a signal at said tuning input terminal, and wherein said variation reference terminal outputs a reference signal according to the signal at said compensating input terminal and said oscillating parameter; and
a compensation bias unit provided with a first input terminal coupled to said variation bias output terminal, a second input terminal coupled to said variation reference terminal, and a compensating output terminal coupled to said compensating input terminal, wherein said compensation bias unit determines the output signal at said compensating output terminal by comparing the signal at said first input terminal with the signal at said second input terminal so as to compensate for the offset of said oscillating parameter and minimize the range of variation of said oscillating gain.

10. The oscillator of claim 9, further comprising:
a fixed current source and an inverter, both provided in said variation bias unit, said fixed current source and a supply voltage terminal of said inverter being coupled to said variation bias output terminal and an input terminal of said inverter being coupled to an output terminal of said inverter;
a current generator and a ring oscillator, both provided in said controlled oscillating unit, said current generator being provided with a control terminal and a current output terminal, said control terminal of said current generator being coupled to said compensating input terminal, said current output terminal being coupled to a supply power terminal of said ring oscillator and forming said variation reference terminal, said current generator determining the magnitude of the output current at said current output terminal according to the signal at said control terminal, said ring oscillator being composed of a plurality of inverters connected to each other in series, wherein one of said inverters is coupled to said control input terminal; and
a differential amplifier, wherein one input terminal of said differential amplifier and the other input terminal of said differential amplifier are coupled to said first input terminal and said second input terminal respectively, and an output terminal of said differential amplifier is coupled to the said variation bias output terminal.

11. The oscillator of claim 9, wherein said variable-parameter element of said tuning unit is a variable capacitor, said variable capacitor being provided with a control terminal, said control terminal being coupled to said tuning input terminal, wherein a signal at said control terminal is used to determine a capacitance of said variable capacitor and one of the two electrode terminals of said variable capacitor is coupled to said control output terminal.

12. The oscillator of claim 10, wherein said variable-parameter element of said tuning unit is a variable capacitor, said variable capacitor being provided with a control terminal, said control terminal being coupled to said tuning input terminal, wherein a signal at said control terminal is used to determine a capacitance of said variable capacitor and one of the two electrode terminals of said variable capacitor is coupled to said control output terminal.
